(19) United States
(12) Patent Application Publication
(10) Pub. No.: US 2024/0363367 A1
(43) Pub. Date: Oct. 31, 2024

(54) METHOD FOR PRODUCING AN ELECTRONIC COMPONENT, AND ELECTRONIC COMPONENT

(71) Applicant: ams-OSRAM International GmbH, Regensburg (DE)

(72) Inventors: Johann Ramchen, Hausen (DE); Jörg Erich Sorg, Regensburg (DE); Klaus Müller, Pettendorf (DE); Jan Marfeld, Regensburg (DE); Steffen Strauss, Nittendorf (DE); Johann Walter, Renningen (DE)

(21) Appl. No.: 18/571,923

(22) PCT Filed: Jun. 13, 2022
(86) PCT No.: PCT/EP2022/066002

§ 371 Date: Dec. 19, 2023

(30) Foreign Application Priority Data
Jun. 23, 2021 (DE) 10 2021 116 237.8

(51) Int. Cl. H01L 21/50; H01L 23/08; H01L 23/10; H01L 23/498

(52) U.S. Cl. CPC H01L 21/50; H01L 23/10; H01L 23/08; H01L 23/498

(57) ABSTRACT

In an embodiment a method includes providing a connecting element having a first main surface, applying a first frame-shaped metallization to or over a carrier and applying a first frame-shaped solder reservoir over the first main surface of the connecting element or applying the first frame-shaped metallization over the first main surface of the connecting element and applying the first frame-shaped solder reservoir over or to the carrier, wherein a width of the first frame-shaped solder reservoir is smaller than a width of the first frame-shaped metallization and liquefying a solder of the first frame-shaped solder reservoir so that a first frame-shaped solder layer is formed which mechanically connects the carrier and the connecting element to one another, the first frame-shaped solder layer having a seam which is formed during liquefying the solder of the first frame-shaped solder reservoir and surrounds the first frame-shaped solder layer.

### CROSS-REFERENCE TO RELATED APPLICATIONS

This patent application is a national phase filing under section 371 of PCT/EP2022/066002, filed Jun. 13, 2022, which claims the priority of German patent application 102021116237.8, filed Jun. 23, 2021, each of which is incorporated herein by reference in its entirety.

### TECHNICAL FIELD

A method of manufacturing an electronic device and an electronic device are disclosed.

### SUMMARY

Embodiments provide an electronic device with an electronic semiconductor chip, which is formed as dense as possible in particular. Further embodiments provide a simple method for manufacturing an electronic device that is as dense as possible.

According to an embodiment of the method, a carrier is provided having a mounting area on which an electronic semiconductor chip is arranged. For example, the mounting area is arranged centrally on the carrier and is surrounded by an edge region. In particular, the electronic semiconductor chip is attached to the mounting area, for example by soldering or adhesion.

According to a further embodiment of the method, a connecting element having a first main surface is provided. For example, the connecting element is frame-shaped. For example, the connecting element has the same or similar geometry as the edge region of the carrier. For example, the connecting element comprises a ceramic, such as Al₃O₂ or AlN. Furthermore, it is also possible that the connecting element consists of a ceramic, such as Al₃O₂ or AlN.

Particularly preferably, the elements described herein as frame-shaped are designed continuously in their entirety. In other words, the elements described as frame-shaped preferably have no gaps.

According to a further embodiment of the method, a first frame-shaped metallization is applied on or over the carrier and a first frame-shaped solder reservoir is applied on or over the first main surface of the connecting member. In particular, the first frame-shaped metallization is applied to or over the edge region of the carrier. For example, the first frame-shaped metallization completely covers the edge region of the carrier. Preferably, in this embodiment, the first frame-shaped metallization completely surrounds the mounting area. Furthermore, it is also possible that the first frame-shaped metallization is applied to or over the first main surface of the connecting element and the first frame-shaped solder reservoir is applied to or over the carrier. In both embodiments, a width of the first frame-shaped solder reservoir is smaller than a width of the first frame-shaped metallization.

The term “over or on” is intended to indicate in particular that the two elements thus related to each other do not necessarily have to be in direct physical contact with each other. Rather, further elements may be arranged in between. In particular, it is also not to be derived from this that elements which are presently “applied to” or arranged “on top of” each other are in direct contact with each other.

According to a further embodiment of the method, the first frame-shaped solder reservoir is arranged on the first frame-shaped metallization. Particularly preferably, the first frame-shaped solder reservoir is arranged completely on the first frame-shaped metallization in plan view. Particularly preferably, the first frame-shaped solder reservoir and the first frame-shaped metallization are in direct contact with each other in this case.

According to a further embodiment of the method, the solder of the first frame-shaped solder reservoir is liquefied so that a first frame-shaped solder layer is formed which mechanically connects the carrier and the connecting element. In particular, the connection between the carrier and the connecting element is mechanically stable. In particular, the solder solidifies after liquefaction so that the solid frame-shaped solder layer is formed. In particular, the first frame-shaped solder layer forms a substance-to-substance bond.

According to a further embodiment of the method, the first frame-shaped solder layer has a seam that forms during liquefaction of the solder of the first frame-shaped solder reservoir and surrounds the first frame-shaped solder layer, preferably completely. In other words, solder escapes laterally during liquefaction and forms a seam. Consequently, the seam is in particular formed of the same material of the solid solder layer and is part of the solid solder layer. In particular, the seam is freely accessible from the outside. The seam has the shape of a meniscus, which is curved outwards as seen from the solid solder layer.

According to a particularly preferred embodiment, the method comprises the following steps:
providing a carrier having a mounting area on which an electronic semiconductor chip is arranged,
providing a connecting element having a first main surface,
applying a first frame-shaped metallization to or over the carrier and applying a first frame-shaped solder reservoir to or over the first main surface of the connecting element, or applying the first frame-shaped metallization to or over the first main surface of the connecting element and applying the first frame-shaped solder reservoir to or over the carrier, wherein a width of the first frame-shaped solder reservoir is less than a width of the first frame-shaped metallization, and
liquefying the solder of the first frame-shaped solder reservoir so that a first frame-shaped solder layer is formed that mechanically connects the carrier and the connecting element.

Preferably, the steps are performed in the above given sequence.

According to a further embodiment of the method, the first frame-shaped solder reservoir is arranged on a further frame-shaped metallization having a width which is greater than the width of the first frame-shaped solder reservoir. In other words, the first frame-shaped solder reservoir is arranged between the first frame-shaped metallization and the further frame-shaped metallization. In particular, the first frame-shaped solder reservoir is applied to the further frame-shaped metallization.

The first metallization and the further metallization each preferably have a width that is greater than the width of the first frame-shaped solder reservoir. In this way, a step is formed between the first frame-shaped solder reservoir and the respective adjacent frame-shaped metallization. As the solder liquefies, the solder distributes to the regions of metallization to form the first frame-shaped solder layer. Since an area of the first frame-shaped solder reservoir in a plan view of the first frame-shaped solder layer is smaller than an area of the first frame-shaped solder layer, the first frame-shaped solder layer does not have contamination in the peripheral areas that often occurs on the surface of the first frame-shaped solder reservoir due to oxidation. Thus, the first frame-shaped solder layer is particularly stable.

According to a further embodiment of the method, a side surface of the first frame-shaped metallization and/or a side surface of the further frame-shaped metallization are wettable for the solder of the first frame-shaped solder reservoir. The side surface of the first frame-shaped metallization and/or the side surface of the further frame-shaped metallization extends in particular from the carrier to the connecting element. The side surface of the first frame-shaped metallization and/or the side surface of the further frame-shaped metallization is, for example, perpendicular to the first main surface of the connecting element.

According to a further embodiment of the method, the solder of the first frame-shaped solder reservoir covers the side surface of the first frame-shaped metallization and/or the side surface of the further frame-shaped metallization during liquefaction, so that a seam of solder is formed on the side surface. This is possible, in particular, if the side surface is wettable for the solder of the first frame-shaped solder reservoir. In particular, the seam is formed from the solder during solidification. Particularly preferably, the seam is arranged completely circumferentially around the side surface of the first frame-shaped metallization and/or the further frame-shaped metallization. The seam advantageously contributes to the mechanical stabilization of the connection between the carrier and the connecting element.

According to a further embodiment of the method, the first frame-shaped solder reservoir is arranged on a further frame-shaped metallization which is wettable for the solder of the first frame-shaped solder reservoir. In particular, the first frame-shaped solder reservoir is applied to the further frame-shaped metallization. In this case, the first frame-shaped metallization has, in particular, a width that is greater than a width of the further frame-shaped metallization and, during liquefaction, a seam is formed that covers a main surface of the first frame-shaped metallization and a side surface of the further frame-shaped metallization. Particularly preferably, in this embodiment, the first frame-shaped metallization is formed to be significantly thinner than the further frame-shaped metallization. In particular, the first frame-shaped metallization is so thin that its side surface is not wetted by the solder. In this embodiment, the seam is formed in the regions of a main surface of the first frame-shaped metallization that are not covered by the further metallization, and on the side surfaces of the further metallization. In particular, an outer surface of the seam has the shape of a meniscus.

Finally, it is also possible for the first frame-shaped solder reservoir to be arranged on a further frame-shaped metallization whose width is greater than the width of the first frame-shaped metallization. In this case, a seam is formed during liquefaction which covers a main surface of the further frame-shaped metallization and a side surface of the first metallization. Particularly preferably, the further frame-shaped metallization in this embodiment is significantly thinner than the first frame-shaped metallization. In particular, the further frame-shaped metallization is so thin that its side surface is not wetted by the solder. In this embodiment, the seam is formed in the regions of a main surface of the further frame-shaped metallization that are not covered by the first metallization and on the side surfaces of the first metallization. In particular, an outer surface of the seam has the shape of a meniscus.

According to a further embodiment of the method, a further frame-shaped solder reservoir having a width smaller than the width of the first frame-shaped metallization is applied to the first frame-shaped metallization. The first frame-shaped solder reservoir and the further frame-shaped solder reservoir are brought into direct contact with each other when the first frame-shaped solder reservoir is arranged on the first frame-shaped metallization, in particular. When the solder of the first frame-shaped solder reservoir is liquefied, a solder of the further frame-shaped solder reservoir is now also liquefied, so that the first frame-shaped solder layer comprises solder of the first frame-shaped solder reservoir and solder of the further frame-shaped solder reservoir. If a seam is formed on the side surfaces of the metallizations, it comprises solder of the first frame-shaped solder reservoir as well as solder of the further frame-shaped solder reservoir. In particular, in this case the side surface of the first metallization can also be wetted by the solder of the further solder reservoir.

According to a further embodiment of the method, a second frame-shaped metallization is applied to a second main surface of the connecting element that is opposite the first main surface. Further, a second frame-shaped solder reservoir is applied on or over a cover element. Further, it is also possible that the second frame-shaped metallization is applied to the cover element and the second frame-shaped solder reservoir is applied on or over the second main surface of the connecting element. In this case, a side surface of the second frame-shaped metallization extends in particular from the cover element to the connecting element. For example, the side surface of the second frame-shaped metallization is perpendicular to the second main surface of the connecting element.

According to a further embodiment of the method, the second frame-shaped solder reservoir is arranged on the second frame-shaped metallization, preferably in direct contact. Particularly preferably, the second frame-shaped solder reservoir is arranged completely on the second frame-shaped metallization in plan view of the second frame-shaped metallization.

According to a further embodiment of the method, the solder of the second frame-shaped solder reservoir is liquefied so that a second frame-shaped solder layer is formed, which mechanically stably connects the connecting element and the cover element.

Here, it is also possible that a further frame-shaped solder reservoir is arranged on the second frame-shaped metallization, the width of which is smaller than the width of the second frame-shaped metallization.

Particularly preferably, the cover element and the carrier are part of a cavity in which the electronic semiconductor chip is arranged. Side walls of the cavity are formed, for example, by the metallizations and the solder layers as well as the connecting element. A bottom surface of the cavity comprises, for example, the mounting area of the carrier. Particularly preferably, the cavity is hermetically sealed from an external region. In particular, gaseous and/or liquid contaminants from the external region cannot penetrate the cavity or can penetrate only to a negligible extent.

Furthermore, it is also possible for the cover element to be applied directly to the connecting element and to be formed integrally with the connecting element, for example. In this case, too, a cavity is preferably formed, which is preferably sealed as tightly as possible from the external space.

According to a further embodiment of the method, the first metallization and/or the second metallization and/or the further metallization comprises or consists of copper.

According to a further embodiment of the method, the solder of the first frame-shaped solder reservoir and the solder of the second frame-shaped solder reservoir are liquefied simultaneously. For example, the solder of the first frame-shaped solder reservoir and the solder of the second frame-shaped solder reservoir comprise the same solder or consist of the same solder. If a further solder reservoir is used, the solder of the further solder reservoir can also be liquefied simultaneously with the solder of the first solder reservoir and the solder of the second solder reservoir.

According to a further embodiment of the method, the solder is liquefied by pressure. In particular, solder emerges at the side surface of the first frame-shaped metallization and/or at the side surface of the second metallization and/or at the side surface of the further frame-shaped metallization and wets the side surface of the first frame-shaped metallization and/or the side surface of the second metallization and/or the side surface of the further frame-shaped metallization. Pressing out and wetting can advantageously form seams from the solder on the side surface of the respective metallization, which additionally contribute to the hermetic encapsulation of the cavity and further mechanically stabilize the electronic device.

For example, the first solder reservoir and/or the second solder reservoir and/or the further solder reservoir are formed as a layer with a comparatively homogeneous thickness. For example, the first solder reservoir and/or the further solder reservoir and/or the second solder reservoir has a thickness between and including 4 micrometers and 8 micrometers.

According to a further embodiment of the method, the first solder reservoir and/or the further solder reservoir and/or the second solder reservoir has a width of at least 200 micrometers.

According to a further embodiment of the method, the first solder reservoir and/or the further solder reservoir and/or the second solder reservoir comprises AuSn having a composition between and including 70:30 and 80:20. In other words, the first solder reservoir and/or the further solder reservoir and/or the second solder reservoir comprises an alloy of gold and tin, with gold having a weight fraction between and including 70% and 80% and tin having a weight fraction between and including 20% and 30%.

The first solder reservoir and/or the further solder reservoir and/or the second solder reservoir can be applied, for example, by one of the following methods: galvanic deposition, evaporation, PVD (short for “physical vapor deposition”), sputtering.

According to a further embodiment of the method, a solder barrier layer is arranged between the first frame-shaped metallization and the first frame-shaped solder reservoir. A solder barrier layer can also be arranged between the further frame-shaped metallization and the first frame-shaped solder reservoir and/or between the second frame-shaped metallization and the second frame-shaped solder reservoir and/or between the first frame-shaped metallization and the further solder reservoir. In particular, the solder barrier layer is provided and arranged to at least reduce penetration of the solder into the metallization, in particular during liquefaction. Preferably, the solder barrier layer is in direct contact with the metallization.

For example, the solder barrier layer may comprise gold or be formed of gold. For example, the solder barrier layer comprising gold or formed from gold has a thickness of at most 300 nanometers, preferably of at most 200 nanometers, and particularly preferably of at most 100 nanometers. Furthermore, the solder barrier layer may also comprise nickel or platinum or be formed of nickel or platinum. Furthermore, it is possible that different solder barrier layers are used. For example, a thin gold layer, a nickel layer and a platinum layer can be used as solder barrier layers in the electronic device.

According to a further embodiment of the method, an antioxidation layer is arranged on a surface of the first solder reservoir and/or on a surface of the further solder reservoir and/or on a surface of the second solder reservoir, preferably in direct contact. For example, the antioxidation layer comprises gold or is formed of gold. A thickness of the antioxidation layer, in particular if formed of gold, is for example between and including 0.05 micrometers and 0.2 micrometers. In particular, the antioxidation layer is provided and configured to at least reduce oxidation of the underlying solder.

According to a further embodiment of the method, the first frame-shaped solder layer and/or the second frame-shaped solder layer are free of contamination in edge regions. Contaminations can form within the solder layers, in particular due to oxidation effects and contamination on the surface of the solder reservoir prior to bonding with the metallization. Since the solder reservoir is set back relative to the metallization and the solder is liquefied by the pressing on during bonding so that it is pressed out laterally, areas are formed in the edge regions of the solder layers which are free of contamination or have only a negligible amount of contamination.

According to a further embodiment, the method is carried out under an oxygen-containing atmosphere. Preferably, the formation of the solid solder layers is carried out under an oxygen-containing atmosphere.

In the present method, a joining element is generated which joins two elements, for example the carrier and the connecting element or the connecting element and the cover element, in a materially and mechanically stable manner. The joining element is generated from at least one frame-shaped solder reservoir and at least one frame-shaped metallization, which are arranged on opposite surfaces of the elements to be joined. This frame-shaped solder reservoir is referred to as first frame-shaped solder reservoir or second frame-shaped solder reservoir, while the frame-shaped metallization is referred to as first frame-shaped metallization or second frame-shaped metallization. A further metallization may be arranged underneath the first/second solder reservoir, and is herein referred to as such. Among other things, the further metallization provides a further side surface on which a seam can be formed. Finally, a further frame-shaped solder reservoir can be present on the first/second frame-shaped metallization, which is not mandatory.

The method described herein is based in particular on the idea that the solder reservoir is retracted from the metallization. In this way, a particularly stable joint can be generated, since in particular residues on the surface of the solder reservoir do not or only slightly penetrate into an edge region during liquefaction. This increases the stability of the joint. The generation of two connections via one metallization and one solder reservoir each in an electronic device is explicitly described here. It is understood that multiple solder reservoirs and metallizations can also be used to generate multiple solder layers in the electronic device. Furthermore, all features and embodiments described in connection with one metallization or one solder reservoir can also be designed continuously for all other metallizations or solder reservoirs.

The method is intended and configured to generate an electronic device. All features and embodiments described herein in connection with the method can also be embodied in the electronic device and vice versa.

According to an embodiment, the electronic device comprises a carrier on which an electronic semiconductor chip and a first frame-shaped metallization are arranged. The first frame-shaped metallization surrounds the electronic semiconductor chip, particularly preferably completely.

According to a further embodiment, the electronic device comprises a connecting element having a first main surface.

According to a further embodiment of the electronic device, a first frame-shaped solder layer mechanically connects the first frame-shaped metallization and the connecting element.

According to a further embodiment, the first frame-shaped solder layer has a seam on a side surface of the first frame-shaped metallization.

According to a preferred embodiment, the electronic device comprises a carrier on which an electronic semiconductor chip and a first frame-shaped metallization are arranged, the first frame-shaped metallization surrounding the electronic semiconductor chip. Further, the electronic device comprises a connecting element having a first main surface, wherein a first frame-shaped solder layer mechanically interconnects the first frame-shaped metallization and the connecting element, and the first frame-shaped solder layer has a seam on a side surface of the first frame-shaped metallization.

The carrier, the cover element, the connecting element, the metallizations and/or the solder layers form, in particular, a package for the electronic semiconductor chip. Preferably, the package is formed of inorganic materials. This allows volatile organic materials to be reduced in the cavity.

In particular, it is advantageously possible to provide a very dense encapsulation of the electronic semiconductor chip with the method described herein. Preferably, the encapsulation under a helium leakage test shows a value of at most 1*10⁻⁹ mbar*l/s.

According to a further embodiment, the electronic device comprises a cover element on which a second frame-shaped metallization is arranged, and a second solid solder layer mechanically connecting the connecting element to the cover element, the second solid solder layer having a seam on a side surface of the second frame-shaped metallization.

According to a further embodiment of the electronic device, the electronic semiconductor chip is a light emitting diode chip, a laser diode chip or a sensor. The electronic device may also comprise a plurality of identical or different electronic semiconductor chips, for example light emitting diode chips and/or laser diode chips and/or sensors.

Further advantageous embodiments and developments of the method and the electronic device result from the exemplary embodiment described below in connection with the Figures.

### BRIEF DESCRIPTION OF THE DRAWINGS

FIGS. 1 to 5 each show schematic sectional views of a stage of a method for manufacturing an electronic device according to an exemplary embodiment;

FIG. 6 shows a schematic sectional view of an electronic device according to an exemplary embodiment;

FIG. 7 shows a schematic sectional view of a stage of a method for manufacturing an electronic device according to a further exemplary embodiment;

FIG. 8 shows a schematic sectional view of a stage of a method for manufacturing an electronic device according to a further exemplary embodiment; and

FIGS. 9 and 10 each shows a schematic sectional view of a stage of a method for manufacturing an electronic device according to a further exemplary embodiment.

### DETAILED DESCRIPTION OF ILLUSTRATIVE EMBODIMENTS

Elements that are identical, similar or have the same effect are given the same reference signs in the Figures. The Figures and the proportions of the elements shown in the Figures are not to be regarded as true to scale. Rather, individual elements, in particular layer thicknesses, may be shown exaggeratedly large for better representability and/or understanding.

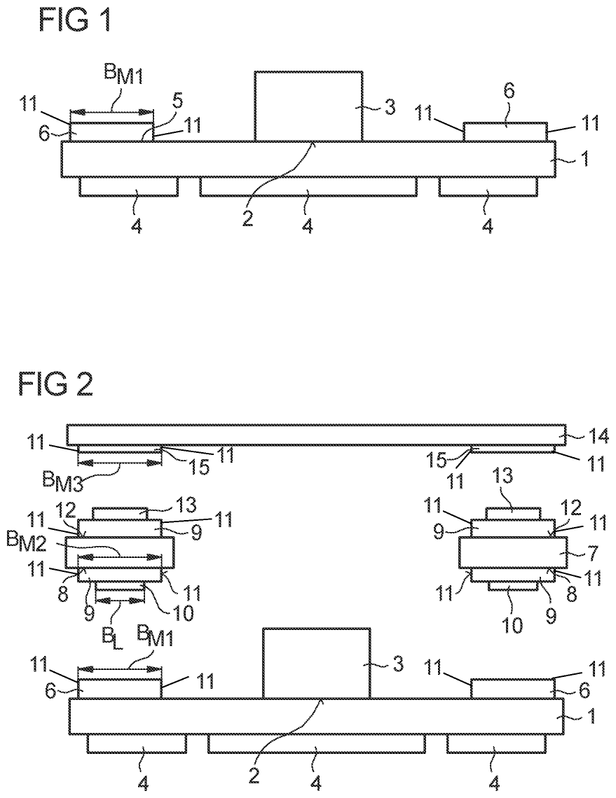

In the method according to the exemplary embodiment of FIGS. 1 to 5, a carrier 1 with a mounting area 2 is first provided, to which an electronic semiconductor chip 3 is attached (FIG. 1). For example, the electronic semiconductor chip 3 is an optoelectronic semiconductor chip, such as a light emitting diode chip or a laser diode chip. Furthermore, the electronic semiconductor chip 3 may be a sensor. Furthermore, the carrier 1 has rear-side electrical connection points 4 via which the electronic device can be contacted electrically.

An edge region 5 is arranged circumferentially around the mounting area 2 of the carrier 1. A first frame-shaped metallization 6 is applied to the edge region 5, which completely surrounds the electronic semiconductor chip 3 on the mounting area 2. In particular, the first frame-shaped metallization 6 on the carrier 1 has no perforations and a constant width B_{M1}.

In a further step, shown schematically in FIG. 2, a connecting element 7 is provided. The connecting element 7 has, for example, a ceramic such as Al₃O₂ or AlN. A further frame-shaped metallization 9 is arranged in direct contact on a first main surface 8 of the connecting element 7. On the further frame-shaped metallization 9 there is a first frame-shaped solder reservoir 10, the width B_{L} of which is smaller than the width B_{M1} of the first frame-shaped metallization 6. In other words, a side surface of the first frame-shaped solder reservoir 10 is arranged set back relative to a side surface 11 of the first frame-shaped metallization 6.

The further frame-shaped metallization 9 has a width B_{M2}. Presently, the first frame-shaped metallization 6 and the further frame-shaped metallization 9 have the same width. In other words, the first frame-shaped metallization 6 and the further frame-shaped metallization 9 are formed wider than the first frame-shaped solder reservoir 10. The first frame-shaped solder reservoir 10 is arranged centrally with respect to the first frame-shaped metallization 6 and the further frame-shaped metallization 9.

A second frame-shaped solder reservoir 13 is applied to a second main surface 12 of the connecting element 7, which is opposite the first main surface 8. Between the second main surface 12 of the connecting element 7 and the second frame-shaped solder reservoir 13 there is a further frame-shaped metallization 9 whose width B_{M2} is greater than a width B_{L} of the second frame-shaped solder reservoir 13.

Furthermore, a cover element 14 is provided on which a second frame-shaped metallization 15 is arranged. A width B_{M3} of the second frame-shaped metallization 15 is greater than a width B_{L} of the second frame-shaped solder reservoir 13. The cover element 14 is, for example, transparent to electromagnetic radiation. For example, the cover element 14 comprises glass or is formed from glass. Furthermore, it is also possible that the cover element 14 comprises a ceramic, such as Al₃O₂ or AlN, or consists of a ceramic.

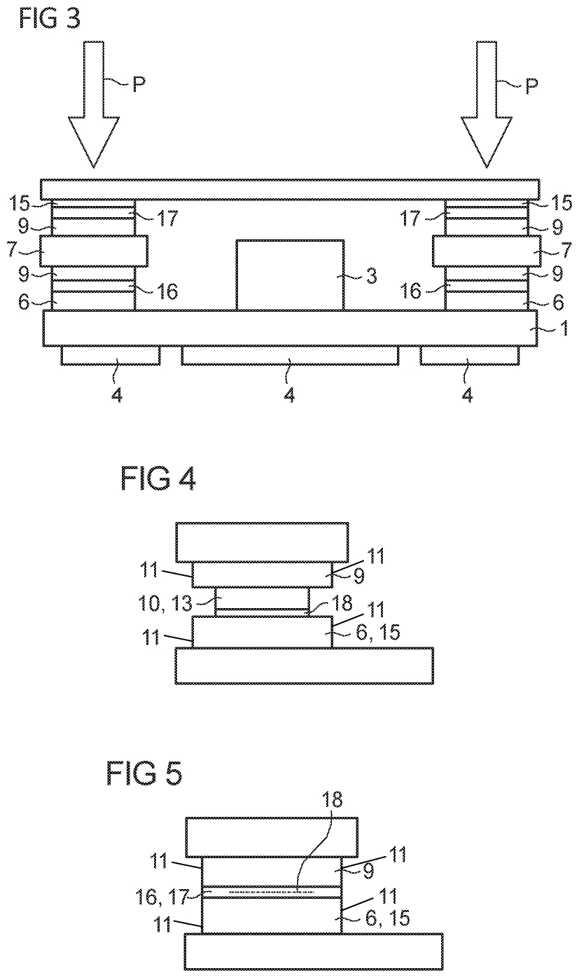

Now the first frame-shaped solder reservoir 10 on the first main surface 8 of the connecting element 7 is brought into direct contact with the first frame-shaped metallization 6 on the carrier 1. The second frame-shaped metallization 15 is also brought into direct contact with the second frame-shaped solder reservoir 13 (FIG. 3). Then, a solder of the first frame-shaped solder reservoir 10 and the solder of the second frame-shaped solder reservoir 13 are liquefied by a pressure P so that a first solid solder layer 16 is formed from the solder of the first frame-shaped solder reservoir 10 between the first frame-shaped metallization 6 and the further frame-shaped metallization 9 on the first main surface 8 of the connecting element 7 and a second solid solder layer 17 is formed between the further frame-shaped metallization 15 on the second main surface 12 of the connecting element 7 and the second frame-shaped metallization 15 on the cover element 14.

FIGS. 4 and 5 schematically show the section between two frame-shaped metallizations 6, 9, 15 and a frame-shaped solder reservoir 10, 13, which is arranged between the two frame-shaped metallizations 6, 9, 15. The following explanations apply regardless of whether a first solid solder layer 16 is generated between the connecting element 7 and the carrier 1 or a second solid solder layer 17 is generated between the connecting element 7 and the carrier 1. Therefore, a corresponding identification of the frame-shaped solder reservoir 10, 13 and the frame-shaped metallization 6, 15 opposite the frame-shaped solder reservoir 10, 13 is omitted in the following.

As FIG. 4 shows, contamination 18 may be present on a surface of the frame-shaped solder reservoir 10, 13, for example due to oxidation and/or deposits. If the frame-shaped solder reservoir 10, 13 is now applied to the frame-shaped metallization 6, 15 for bonding and melted, for example by pressure, a solder of the frame-shaped solder reservoir 10, 13 flows laterally during liquefaction into edge regions of the frame-shaped metallizations 6, 15 which are free of the frame-shaped solder reservoir 10, 13 before liquefaction. In this way, contaminations 18 are trapped inside the solid frame-shaped solder layers 16, 17 that are formed, while edge regions of the solid frame-shaped solder layers 16, 17 remain free of contaminations 18 (FIG. 5). In this way, a particularly stable joint can be generated via the solid frame-shaped solder layers 16, 17.

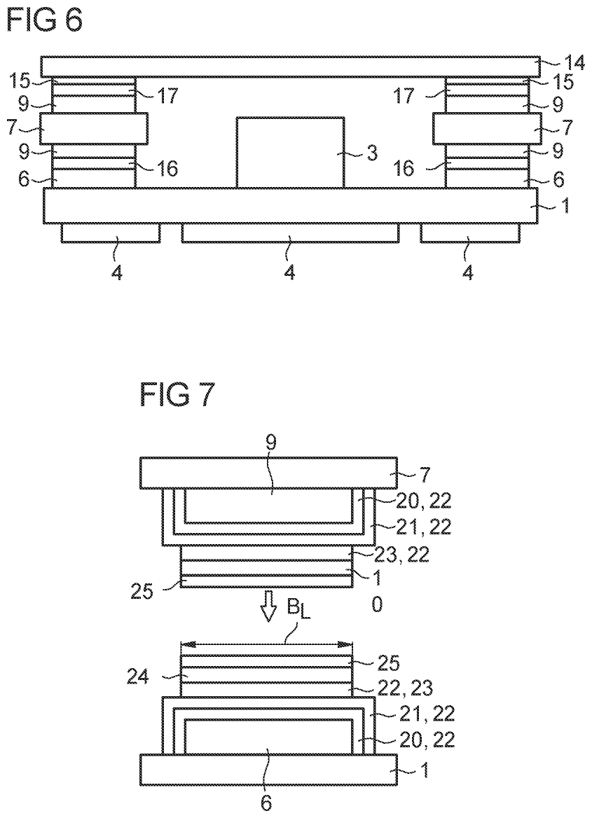

The electronic device according to the exemplary embodiment of FIG. 6 is generated by the method already described with reference to FIGS. 1 to 5.

The electronic device according to the exemplary embodiment of FIG. 6 has an electronic semiconductor chip 3 arranged in a cavity 19. The electronic semiconductor chip 3 is arranged on a mounting area 2 of a carrier 1. Furthermore, the electronic device comprises side surfaces, which in the present case are formed by a connecting element 7, by frame-shaped metallizations 6, 9, 15 and by frame-shaped solder layers 16, 17.

In particular, the electronic device comprises a first frame-shaped metallization 6 arranged on the carrier 1 and a second frame-shaped metallization 15 arranged on the cover element 7. A further frame-shaped metallization 9 is arranged on a first main surface 8 of the connecting element 7 and on a second main surface 12 of the connecting element 7, respectively. A first frame-shaped solder layer 16 is arranged between the first frame-shaped metallization 6 and the further frame-shaped metallization 9 on the first main surface 8 of the connecting element 7, which connects the connecting element 7 and the carrier 1 to each other in a materially and mechanically stable manner. Also arranged between the second frame-shaped metallization 15 and the further frame-shaped metallization 9 on the second main surface 12 of the connecting element 7 is a second frame-shaped solder layer 17, which connects the connecting element 7 and the cover element 14 to one another in a materially bonded and mechanically stable manner.

FIG. 7 shows a section between a carrier and a connecting element in a method according to a further embodiment. Similarly, a corresponding section can be formed between the connecting element and a cover element.

In the method according to the exemplary embodiment of FIG. 7, in contrast to the method according to the exemplary embodiment of FIGS. 1 to 3, a further frame-shaped solder reservoir 24 is arranged on the first frame-shaped metallization 6. Also, a width of the further frame-shaped solder reservoir 24 is smaller than a width B_{M1} of the first frame-shaped metallization 6.

The frame-shaped solder reservoirs 10, 24 do not cover side surfaces 11 of the frame-shaped metallization 6, 9 in this case.

A nickel layer 20 and a gold layer 21 are arranged as solder barrier layers 22 on each frame-shaped metallization 6, 9. The nickel layer 20 and the gold layer 21 completely cover side surfaces 11 of the frame-shaped metallization 6, 9. In particular, the gold layer 21 is freely accessible from the outside. In this way, the side surfaces 11 of the frame-shaped metallization 6, 9 are designed to be wettable for solder of the frame-shaped solder reservoirs 10, 24.

A platinum layer 23 is arranged between the gold layer 21 and the frame-shaped solder reservoir 10, 24, which is also formed as a solder barrier layer 22. The platinum layer 23 does not cover the side surfaces 11 of the frame-shaped metallization 6, 9, but has the same width B_{L} as the frame-shaped solder reservoir 10, 24. Furthermore, an antioxidation layer 25 is arranged on the frame-shaped solder reservoir 10, 24, which completely covers the frame-shaped solder reservoir 10, 24. In the present case, the antioxidation layer 25 is formed of gold.

The two frame-shaped solder reservoirs 10, 24 are brought together and liquefied by pressure to form a mechanically stable first frame-shaped solder layer 16 (not shown).

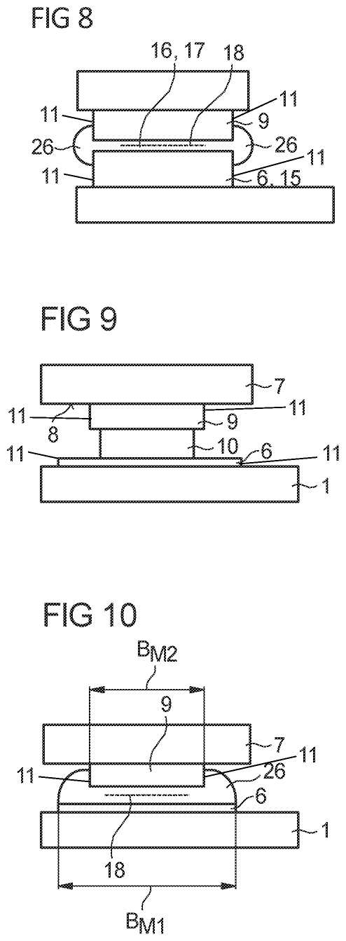

FIG. 8 shows a section of the connection of a connecting element 7 to a carrier 1 or of a connecting element 7 to a cover element. Accordingly, the frame-shaped metallizations 6, 9, 15 and the frame-shaped solder reservoir 10, 13 have not been marked accordingly. Such a connection can also be generated between the connecting element 7 and the cover element 14.

In the method according to the exemplary embodiment of FIG. 8, the side surfaces 11 of the frame-shaped metallizations 6, 9, 15 are designed to be wettable for the solder of the frame-shaped solder reservoir 10, 13. When the frame-shaped solder reservoir 10, 13 is pressed onto one another and liquefied, solder emerges from the side surfaces 11 of the frame-shaped metallizations 6, 9, 15, wets the side surfaces 11 of the frame-shaped metallizations 6, 9, 15 and forms a solid frame-shaped solder layer 16, 17 with circumferential seams 26.

In the method according to the exemplary embodiment of FIGS. 9 and 10, a first frame-shaped metallization 6 is applied to a carrier 1 and a further frame-shaped metallization 9 is applied to a first main surface 8 of a connecting element 7. A width B_{M1} of the first frame-shaped metallization 6 is greater than a width B_{M2} of the further frame-shaped metallization 9. At the same time, the first frame-shaped metallization 6 is thinner than the further frame-shaped metallization 9. A first frame-shaped solder reservoir 10 is formed on the further frame-shaped metallization 9 (FIG. 9).

In a next step, the first frame-shaped solder reservoir 10 is liquefied so that the solder emerges laterally from the side surfaces 11 of the further frame-shaped metallization 9 and wets both the side surfaces 11 of the further frame-shaped metallization 9 and a main surface of the first frame-shaped metallization 6.

After solidification of the solder of the first solder reservoir 10, a first solid frame-shaped solder layer 16 is formed, which connects the carrier 1 and the connecting element 7 to each other in a materially and mechanically stable manner. A seam 26 is formed on the side surfaces 11 of the further metallization 9, the outer surface of which has the shape of a meniscus.

The invention is not limited to these by the description based on the embodiments. Rather, the invention encompasses any new feature as well as any combination of features, which in particular includes any combination of features in the patent claims, even if this feature or combination itself is not explicitly stated in the patent claims or embodiments.

1-18. (canceled)

19. A method for manufacturing an electronic device, the method comprising:
providing a carrier having a mounting area on which an electronic semiconductor chip is arranged;
providing a connecting element having a first main surface;
applying a first frame-shaped metallization to or over the carrier and applying a first frame-shaped solder reservoir over the first main surface of the connecting element or applying the first frame-shaped metallization over the first main surface of the connecting element and applying the first frame-shaped solder reservoir over or to the carrier, wherein a width of the first frame-shaped solder reservoir is smaller than a width of the first frame-shaped metallization; and
liquefying a solder of the first frame-shaped solder reservoir so that a first frame-shaped solder layer is formed which mechanically connects the carrier and the connecting element to one another, the first frame-shaped solder layer having a seam which is formed during liquefying the solder of the first frame-shaped solder reservoir and surrounds the first frame-shaped solder layer.

20. The method according to claim 19, wherein the first frame-shaped solder reservoir is arranged on a further frame-shaped metallization which has a width which is greater than the width of the first frame-shaped solder reservoir.

21. The method according to claim 19,
wherein a side surface of the first frame-shaped metallization and/or a side surface of the further frame-shaped metallization is wettable for the solder of the first frame-shaped solder reservoir, and
wherein the solder of the first frame-shaped solder reservoir covers the side surface of the first frame-shaped metallization and/or the side surface of the further frame-shaped metallization during liquefaction so that the seam is formed from the solder on the side surface.

22. The method according to claim 19,
wherein the first frame-shaped solder reservoir is arranged on a further frame-shaped metallization which is wettable for the solder of the first frame-shaped solder reservoir,
wherein the first frame-shaped metallization has a width which is greater than a width of the further frame-shaped metallization, and
wherein the seam is formed during liquefaction, covering a main surface of the first frame-shaped metallization and a side surface of the further metallization.

23. The method according claim 19,
wherein a further frame-shaped solder reservoir, which has a width that is smaller than the width of the first frame-shaped metallization, is applied to the first frame-shaped metallization,
wherein a solder of the further frame-shaped solder reservoir is liquefied when the solder of the first frame-shaped solder reservoir is liquefied, and
wherein the first frame-shaped solder layer comprises solder of the first frame-shaped solder reservoir and the solder of the further frame-shaped solder reservoir.

24. The method according to claim 19,
wherein a second frame-shaped metallization is applied to a second main surface of the connecting element, which is opposite the first main surface, and a second frame-shaped solder reservoir is applied above or on a cover element, or the second frame-shaped metallization is applied to the cover element and the second frame-shaped solder reservoir is applied on or above the second main surface of the connecting element, and
wherein a solder of the second frame-shaped solder reservoir is liquefied so that a second frame-shaped solder layer is formed which mechanically connects the connecting element and the cover element to each other.

25. The method according to claim 24, wherein the liquefaction of the solder of the first frame-shaped solder reservoir and the solder of the second frame-shaped solder reservoir takes place simultaneously.

26. The method according to claim 19, wherein the solder is liquefied by pressure.

27. The method according to claim 24, wherein the first frame-shaped solder reservoir and/or the further frame-shaped solder reservoir and/or the second frame-shaped solder reservoir has a thickness of between and including 4 micrometers and 8 micrometers.

28. The method according to claim 24, wherein the first frame-shaped solder reservoir and/or the further frame-shaped solder reservoir and/or the second frame-shaped solder reservoir has a width of at least 200 micrometers.

29. The method according to claim 24, wherein the first frame-shaped solder reservoir and/or the further frame-shaped solder reservoir and/or the second frame-shaped solder reservoir comprises AuSn having a composition between 70:30 and 80:20, inclusive.

30. The method according to claim 24, wherein the first frame-shaped solder reservoir and/or the further frame-shaped solder reservoir and/or the second frame-shaped solder reservoir is applied by one of the following methods: galvanic deposition, evaporation, PVD, or sputtering.

31. The method according to claim 24,
wherein a solder barrier layer is arranged between the first frame-shaped metallization and the first frame-shaped solder reservoir, and/or
wherein a solder barrier layer is arranged between the further frame-shaped metallization and the first frame-shaped solder reservoir, and/or
wherein a solder barrier layer is arranged between the first frame-shaped metallization and the further frame-shaped solder reservoir, and/or
wherein a solder barrier layer is arranged between the second frame-shaped metallization and the second frame-shaped solder reservoir.

32. The method according to claim 24, wherein an antioxidation layer is arranged on a surface of the first frame-shaped solder reservoir and/or of the further frame-shaped solder reservoir and/or of the second frame-shaped solder reservoir.

33. The method according to claim 24, wherein the first frame-shaped solder layer and/or the second frame-shaped solder layer is free of contamination in edge regions.

34. An electronic device comprising:
a carrier on which an electronic semiconductor chip and a first frame-shaped metallization are arranged, wherein the first frame-shaped metallization surrounds the electronic semiconductor chip; and
a connecting element with a first main surface, wherein a first frame-shaped solder layer mechanically connects the first frame-shaped metallization and the connecting element, and wherein the first frame-shaped solder layer has a seam on a side surface of the first frame-shaped metallization.

35. The electronic device according to claim 34, further comprising:
a cover element on which a second frame-shaped metallization is arranged; and
a second solid solder layer mechanically connecting the connecting element to the cover element, the second solid solder layer having a seam on a side surface of the second frame-shaped metallization.

36. The electronic device according to claim 34, wherein the electronic semiconductor chip is a light emitting diode chip, a laser diode chip or a sensor.
